(19) United States
(12) Patent Application Publication
(10) Pub. No.: US 2025/0247053 A1
(43) Pub. Date: Jul. 31, 2025

(54) FRONT END MODULE AND OPERATING METHOD THEREOF

(71) Applicant: Samsung Electro-Mechanics Co., Ltd., Suwon-si (KR)

(72) Inventors: Byeonghak JO, Suwon-si (KR); Gyu-Suck KIM, Suwon-si (KR); Taeho LIM, Suwon-si (KR); Wonsun HWANG, Suwon-si (KR)

(73) Assignee: Samsung Electro-Mechanics Co., Ltd., Suwon-si (KR)

(21) Appl. No.: 18/804,499

(22) Filed: Aug. 14, 2024

(30) Foreign Application Priority Data
Jan. 25, 2024 (KR) 10-2024-0011523
Mar. 25, 2024 (KR) 10-2024-0040297

(51) Int. Cl. H03F 1/26; H03F 1/56; H03F 3/24; H04B 1/12; H04B 1/40

(52) U.S. Cl. CPC H03F 1/26; H03F 1/56; H03F 3/245; H04B 1/123; H04B 1/40; H03F 2200/222; H03F 2200/294; H03F 2200/387; H03F 2200/451

(57) ABSTRACT

A front end module includes a low noise amplifier configured to amplify a receiving signal; a power amplifier configured to amplify a transmitting signal; a first switch positioned in a first path that bypasses the low noise amplifier and configured to form the first path; and a second switch positioned in the first path, connected to the first switch at a first node in the first path, and configured to form the first path together with the first switch, wherein an output terminal of the power amplifier is connected to the first node.

### CROSS-REFERENCE TO RELATED APPLICATIONS

This application claims the benefit under 35 USC 119(a) of Korean Patent Application Nos. 10-2024-0011523 filed on Jan. 25, 2024, and 10-2024-0040297 filed on Mar. 25, 2024, in the Korean Intellectual Property Office, the entire disclosures of which are incorporated herein by reference for all purposes.

### BACKGROUND

### 1. Field

The following description relates to a front end module and an operating method thereof.

### 2. Description of Related Art

A front end module is a module that performs signal processing at the input end or output end of a wireless communication system. The front end module may include a low noise amplifier, a power amplifier, and a switch.

The low noise amplifier amplifies a weak signal received through an antenna into a signal having a high signal-to-noise ratio, and the power amplifier amplifies the signal to generate a transmitting signal and outputs the transmitting signal to the antenna. The switch may switch path settings for transmitting signals and receiving signals. Among the main characteristics of low noise amplifiers, a noise figure is an important factor in determining reception sensitivity.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a front end module includes a low noise amplifier configured to amplify a receiving signal; a power amplifier configured to amplify a transmitting signal; a first switch positioned in a first path that bypasses the low noise amplifier and configured to form the first path; and a second switch positioned in the first path, connected to the first switch at a first node in the first path, and configured to form the first path together with the first switch, wherein an output terminal of the power amplifier is connected to the first node.

In a reception bypass mode, the first switch and the second switch may be further configured to be turned on to form the first path to enable the receiving signal to pass through the first path formed by the first switch and the second switch.

In a transmission mode, the first switch may be further configured to be turned on and the second switch may be further configured to be turned off to enable the transmitting signal to pass through a transmission path formed by the power amplifier and the first switch.

The front end module may further include an antenna terminal configured to receive the receiving signal; and a third switch connected between the antenna terminal and an input terminal of the low noise amplifier.

In a reception mode, the third switch may be configured to be turned on and the first switch and the second switch may be further configured to be turned off to enable the receiving signal to pass through a reception path formed by the antenna terminal, the third switch, and the low noise amplifier.

In a reception bypass mode, the first switch and the second switch may be further configured to be turned on and the third switch may configured to be turned off.

The front end module may further include a fourth switch connected between the input terminal of the low noise amplifier and a ground, wherein the fourth switch may be configured to be turned on in the reception bypass mode.

The front end module may further include a fourth switch connected between the first node and the output terminal of the power amplifier; and a fifth switch connected between the output terminal of the power amplifier and a ground, wherein in the reception bypass mode, the fourth switch may be configured to be turned off and the fifth switch may be configured to be turned on.

The front end module may further include a first matching network including a first terminal connected to the antenna terminal; and a fourth switch connected between a second terminal of the first matching network and a ground, wherein the fourth switch may be configured to be turned on in the reception bypass mode.

In a transmission mode, the first switch may be further configured to be turned on and the second switch and the third switch may be further configured turned off to enable the transmitting signal to pass through a transmission path formed by the power amplifier, the first switch, and the antenna terminal.

The front end module may further include a fourth switch connected between an output terminal of the low noise amplifier and a ground, wherein the fourth switch may be configured to be turned on in the reception mode.

The front end module may further include a first matching network including a first terminal connected to the first node; and a fourth switch connected between a second terminal of the first matching network and a ground, wherein the fourth switch may be configured to turned on in the transmission mode.

The front end module may further include a first matching network positioned in the first path between the first switch and the second switch.

In a reception bypass mode, the first switch and the second switch may be further configured to be turned on to enable the receiving signal to pass through the first path formed by the first switch, the first matching network, and the second switch.

In a transmission mode, the first switch may be further configured to turned on and the second switch may be further configured to be turned off to enable the transmitting signal to pass through a transmission path formed by the power amplifier, the first matching network, and the first switch.

Another general aspect is directed to an operating method of a front end module. The front end module includes an antenna terminal, a receiving terminal, a transmitting terminal, a low noise amplifier including an input terminal connected to the antenna terminal and an output terminal connected to the receiving terminal, a first switch connected between the antenna terminal and a node, a second switch connected between the node and the receiving terminal, and a power amplifier including an input terminal connected to the transmitting terminal and an output terminal connected to the node. The operating method includes, in a first mode, turning off the first switch and the second switch to enable the low noise amplifier to amplify a first receiving signal input from the antenna terminal and output the amplified first receiving signal from the receiving terminal; in a second mode, turning on the first switch and the second switch to enable a second receiving signal input from the antenna terminal to bypass the low noise amplifier and be output from the receiving terminal; and in a third mode, turning on the first switch and turning off the second switch to enable the power amplifier to amplify a transmitting signal input from the transmitting terminal and output the amplified transmitting signal from the antenna terminal.

In the second mode, the second receiving signal may pass through a reception bypass path formed by the antenna terminal, the first switch, the second switch, and the transmission terminal.

In the third mode, the transmitting signal may pass through a transmission path formed by the transmitting terminal, the power amplifier, the first switch, and the antenna terminal.

The front end module may further include a third switch connected between the antenna terminal and the input terminal of the low noise amplifier, and the operating method may further include, in the first mode, turning on the third switch while the first switch and the second switch are turned off so that the first receiving signal passes through a reception path formed by the antenna terminal, the third switch, the low noise amplifier, and the receiving terminal.

The front end module may further include a first matching network connected between the first switch and the node, and, in the second mode, the second receiving signal may pass through a reception bypass path formed by the antenna terminal, the first switch, the first matching network, the second switch, and the transmitting terminal.

Other features and aspects will be apparent from the following detailed description, the drawings, and the claims.

### BRIEF DESCRIPTION OF DRAWINGS

FIG. 1 illustrates a front end module 1000A according to an example.

FIG. 2A is a diagram showing the operation of the front end module 1000A in a reception mode.

FIG. 2B is a diagram showing the operation of the front end module 1000A in a reception bypass mode.

FIG. 2C is a diagram showing the operation of the front end module 1000A in a transmission mode.

FIG. 3 illustrates a front end module 1000B according to another example.

FIG. 4A is a diagram showing the operation of the front end module 1000B in the reception mode.

FIG. 4B is a diagram showing the operation of the front end module 1000B in the reception bypass mode.

FIG. 4C is a diagram showing the operation of the front end module 1000B in the transmission mode.

FIG. 5 illustrates a front end module 1000C according to another example.

FIG. 6A is a diagram showing the operation of the front end module 1000C in the reception mode.

FIG. 6B is a diagram showing the operation of the front end module 1000C in the reception bypass mode.

FIG. 6C is a diagram showing the operation of the front end module 1000C in the transmission mode.

FIG. 7 illustrates a front end module 1000D according to another example.

FIG. 8A is a diagram showing the operation of the front end module 1000D in the reception mode.

FIG. 8B is a diagram showing the operation of the front end module 1000D in the reception bypass mode.

FIG. 8C is a diagram showing the operation of the front end module 1000D in the transmission mode.

FIG. 9 illustrates a front end module 1000E according to another example.

FIG. 10A is a diagram showing the operation of the front end module 1000E in the reception mode.

FIG. 10B is a diagram showing the operation of the front end module 1000E in the reception bypass mode.

FIG. 10C is a diagram showing the operation of the front end module 1000E in the transmission mode.

FIG. 11 illustrates a front end module 1000F according to another example.

FIG. 12A is a diagram showing the operation of the front end module 1000F in the reception mode.

FIG. 12B is a diagram showing the operation of the front end module 1000F in the reception bypass mode.

FIG. 12C is a diagram showing the operation of the front end module 1000F in the transmission mode.

FIG. 13 illustrates a front end module 1000G according to another example.

FIG. 14A is a diagram showing the operation of the front end module 1000G in the reception mode.

FIG. 14B is a diagram showing the operation of the front end module 1000G in the reception bypass mode.

FIG. 14C is a diagram showing the operation of the front end module 1000G in the transmission mode.

FIG. 15 illustrates a front-end module 2000 according to a comparative example.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The use of the term “may” with respect to an example or embodiment, e.g., as to what an example or embodiment may include or implement, means that at least one example or embodiment exists in which such a feature is included or implemented, while all examples and embodiments are not necessarily limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated by 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

In this application, an RF signal includes Wi-Fi (IEEE 802.11 family, etc.), WiMAX (IEEE 802.16 family, etc.), IEEE 802.20, LTE (Long-Term Evolution), EV-DO, HSDPA, HSUPA, HSPA, HSPA+, EDGE, GSM, GPS, GPRS, CDMA, TDMA, DECT, Bluetooth, 3G, 4G, 5G, and any other wireless and wired protocols designated hereafter, but is not limited thereto.

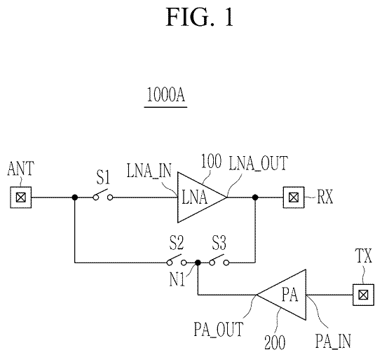

FIG. 1 illustrates a front end module 1000A according to an example.

As shown in FIG. 1, the front end module 1000A may include a low noise amplifier 100, a power amplifier 200, and a plurality of switches S1˜S3.

The front end module 1000A is positioned at the front end of a wireless communication system and may receive and transmit radio frequency (RF) signals. To receive and transmit RF signals, the front end module 1000A may further include an antenna terminal ANT, a receiving terminal RX, and a transmitting terminal TX. The antenna terminal ANT is a terminal connected to an antenna, and may receive an RF receiving signal from the antenna and transmit an RF transmitting signal to the antenna. The receiving terminal RX may transmit the RF receiving signal to a transceiver (not shown in FIG. 1), and the transmitting terminal TX may receive the RF transmitting signal from the transceiver.

The low noise amplifier (LNA) 100 may have an input terminal LNA_IN and an output terminal LNA_OUT. The input terminal LNA_IN of the low noise amplifier 100 receives the RF receiving signal from the antenna terminal ANT. The low noise amplifier 100 may amplify the RF receiving signal input to the input terminal LNA_IN and output the amplified RF receiving signal to the output terminal (LNA_OUT).

The magnitude of the RF receiving signal received from the antenna terminal ANT may vary depending on the surrounding environment. When the magnitude of the RF receiving signal is small, the low noise amplifier 100 may be set to an on state. In other words, the low noise amplifier 100 performs an amplification operation on a small RF receiving signal. When the RF receiving signal is large enough not to require amplification, the low noise amplifier 100 may be set to an off state. When the low noise amplifier 100 is set to the off state, the RF receiving signal may be bypassed without passing through the low noise amplifier 100. Hereinafter, a mode in which the low noise amplifier 100 is set to the on state and the RF receiving signal is amplified is referred to as a ‘reception mode’. Also, a mode in which the low noise amplifier 100 is set to the off state and the RF receiving signal is bypassed without being amplified is referred to as a ‘reception bypass mode’.

The power amplifier (PA) 200 may have an input terminal PA_IN and an output terminal PA_OUT. The input terminal PA_IN of the power amplifier 200 receives the RF transmitting signal from the transmitting terminal TX. The power amplifier 200 may amplify the RF transmitting signal input to the input terminal PA_IN and output the amplified RF transmitting signal to the output terminal PA_OUT. As shown in FIG. 1, the output terminal PA_OUT of the power amplifier 200 may be connected to a node N1 (hereinafter referred to as a ‘first node N1’) where a switch S2 and a switch S3 are connected to each other. Hereinafter, a mode in which the power amplifier 200 is set to an on state and the RF transmitting signal is amplified is referred to as a ‘transmission mode’.

The plurality of switches S1˜S3 may set the path for the RF receiving signal and may set the path for the RF transmitting signal.

The switch S1 may be connected between the antenna terminal ANT and the input terminal LNA_IN of the low noise amplifier 100. That is, a first terminal of the switch S1 may be connected to the antenna terminal (ANT), and a second terminal of the switch S1 may be connected to the input terminal LNA_IN of the low noise amplifier 100. The switch S1 may be turned on in the reception mode and may transmit the RF receiving signal received from the antenna terminal ANT to the input terminal LNA_IN of the low noise amplifier 100. Also, the switch S1 may be turned off in the reception bypass mode and the transmission mode.

A first terminal of the switch S2 may be connected to the antenna terminal ANT, and a second terminal of the switch S2 may be connected to the output terminal PA_OUT of the power amplifier 200. Also, the first terminal of the switch S2 may be connected to the first terminal of the switch S1, and the second terminal of the switch S2 may be connected to a first terminal of the switch S3. In other words, the switch S2 may be positioned in a path (hereinafter referred to as a ‘bypass path’) that bypasses the low noise amplifier 100. The switch S2 may be turned on in the reception bypass mode to form the bypass path. Furthermore, the switch S2 may be turned on in the transmission mode and transmit the amplified RF transmitting signal output from the power amplifier 200 to the antenna terminal ANT. The switch S2 may be turned off in the reception mode.

The switch S3 may be connected between the second terminal of the switch S2 and the output terminal LNA_OUT of the low noise amplifier 100. That is, a first terminal of switch S3 may be connected to the second terminal of the switch S2, and a second terminal of the switch S3 may be connected to the output terminal LNA_OUT of the low noise amplifier 100. Also, the first terminal of the switch S3 may be connected to the output terminal PA_OUT of the power amplifier 200. The switch S3 may be positioned in the bypass path. The switch S3 may be turned on in the reception bypass mode to form the bypass path together with the switch S2. The switch S3 may be turned off in the reception mode and the transmission mode.

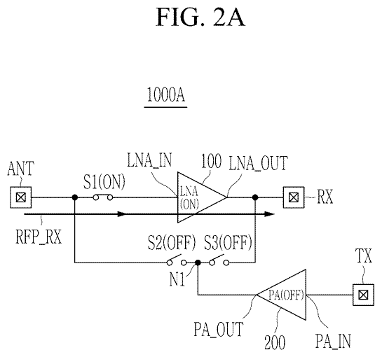

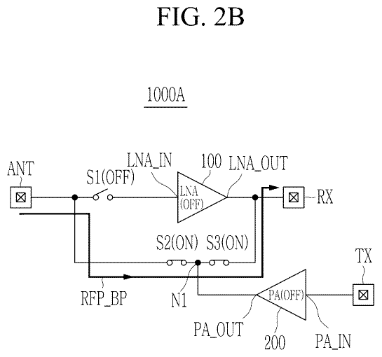

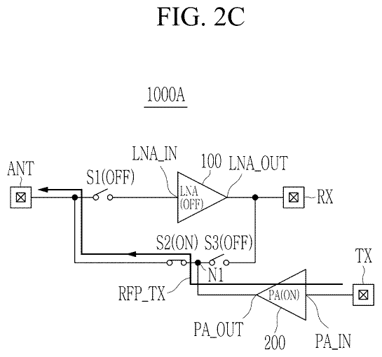

Referring to FIGS. 2A to 2C, the operation of the front end module 1000A in each mode will be described.

FIG. 2A is a diagram showing the operation of the front end module 1000A in the reception mode.

In the reception mode, the switch S1 may be turned on, and the switch S2 and the switch S3 may be turned off. The low noise amplifier 100 may be set to the on state, and the power amplifier 200 may be set to the off state.

As shown in FIG. 2A, in the reception mode, the RF receiving signal may pass through an RF reception path RFP_RX formed by the antenna terminal ANT, the switch S1, the low noise amplifier 100, and the receiving terminal RX.

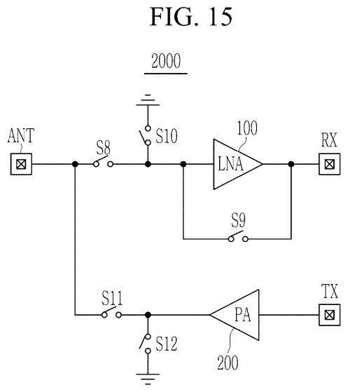

When the RF reception path RFP_RX is formed, the low noise amplifier 100 amplifies the RF receiving signal input to the input terminal LNA_IN. At this time, the RF receiving signal input to the input terminal LNA_IN of the low noise amplifier 100 may suffer a loss due to the switch S1 and the switch S2. The switches that directly affect the RF receiving signal input to the low noise amplifier 100 may be the switch S1 and the switch S2. In the reception mode, the switch S1 is turned on, and the switch S2 is turned off. Accordingly, the RF receiving signal input to the low noise amplifier 100 may suffer a loss due to an insertion loss of the switch S1 that is turned on, and an off-capacitance loss of the switch S2 that is turned off. In the front end module 1000A of FIG. 1, there are two switches (i.e., S1 and S2) that cause a loss in the RF receiving signal, so the loss can be reduced compared to a typical front end module (see FIG. 15 described below). Due to the reduced loss of the RF receiving signal, the front end module 1000A of FIG. 1 may improve the noise figure. In other words, the front end module 1000A may improve the noise figure by reducing the number of switches connected to the input terminal LNA_IN of the low noise amplifier 100.

FIG. 2B is a diagram showing the operation of the front end module 1000A in the reception bypass mode.

In the reception bypass mode, the switch S1 may be turned off, and the switch S2 and the switch S3 may be turned on. The low noise amplifier 100 and the power amplifier 200 may be set to the off state.

As shown in FIG. 2B, in the reception bypass mode, the RF receiving signal may pass through an RF reception bypass path RFP_BP formed by the antenna terminal ANT, the switch S2, the switch S3, and the receiving terminal RX. That is, the RF receiving signal may be output to the receiving terminal RX through the bypass path that bypasses the low noise amplifier 100. Through this, the RF receiving signal may be output directly to the receiving terminal RX without being amplified by the low noise amplifier 100.

FIG. 2C is a diagram showing the operation of the front end module 1000A in the transmission mode.

In the transmission mode, the switch S2 may be turned on, and the switch S1 and the switch S3 may be turned off. The power amplifier 200 may be set to the on state, and the low noise amplifier 100 may be set to the off state.

As shown in FIG. 2C, in the transmission mode, the RF transmitting signal pass through an RF transmission path RFP_TX formed by the transmitting terminal TX, the power amplifier 200, the switch S2, and the antenna terminal ANT.

When the RF transmission path RFP_TX is formed, the power amplifier 200 amplifies the RF transmitting signal input to the input terminal PA_IN. The amplified RF transmitting signal may be output to the antenna terminal ANT through the switch S2.

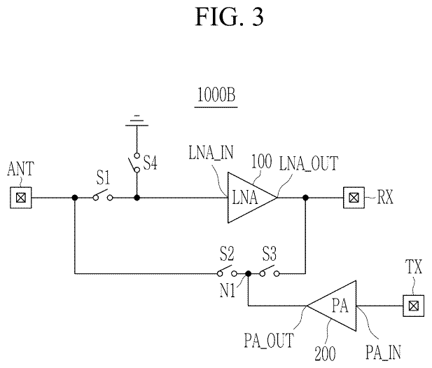

FIG. 3 illustrates a front end module 10001B according to another example.

As shown in FIG. 3, the front end module 1000B may include a low noise amplifier 100, a power amplifier 200, and a plurality of switches S1˜S4. Since the front end module 1000B of FIG. 3 is similar to the front end module 1000A of FIG. 1 except that the switch S4 is added, overlapping descriptions may be omitted.

The plurality of switches S1˜S4 may set the path for the RF receiving signal or set the path for the RF transmitting signal. The connection relationship and operation of the switch S1, the switch S2, and the switch S3 have the same connection relationship and operation as described in FIG. 1.

The switch S4 may be connected between the input terminal LNA_IN of the low noise amplifier 100 and a ground. That is, the switch S4 may be connected between the second terminal of the switch S1 and the ground. The switch S4 may be turned on in the reception bypass mode and the transmission mode. Also, the switch S4 may be turned off in the reception mode. The switch S4 is a shunt switch and operates opposite to the switching operation of the switch S1, thereby improving isolation.

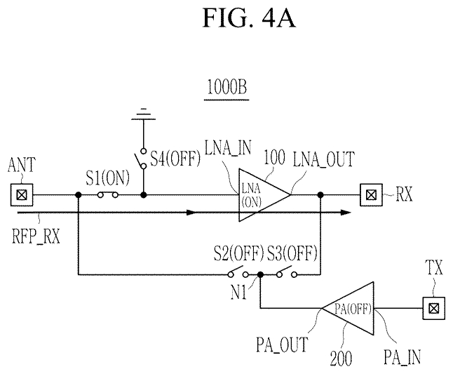

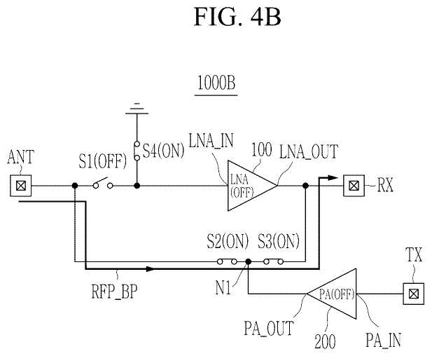

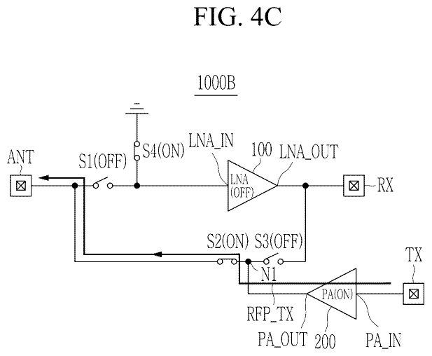

With reference to FIGS. 4A to 4C, the operation of the front end module 1000B in each mode will be described.

FIG. 4A is a diagram showing the operation of the front end module 1000B in the reception mode.

In the reception mode, the switch S1 may be turned on, and the switch S2, the switch S3, and the switch S4 may be turned off. The low noise amplifier 100 may be set to the on state, and the power amplifier 200 may be set to the off state.

As shown in FIG. 4A, in the reception mode, the RF receiving signal may pass through an RF reception path RFP_RX formed by the antenna terminal ANT, the switch S1, the low noise amplifier 100, and the receiving terminal RX.

When the RF reception path RFP_RX is formed, the low noise amplifier 100 amplifies the RF receiving signal input to the input terminal LNA_IN. At this time, the RF receiving signal input to the input terminal LNA_IN of the low noise amplifier 100 may suffer a loss due to the switch S1, the switch S2, and the switch S4. Switches that directly affect the RF receiving signal input to the low noise amplifier 100 may be the switch S1, the switch S2, and the switch S4. In the reception mode, the switch S1 is turned on, and the switch S2 and the switch S4 are turned off. Accordingly, the RF receiving signal input to the low noise amplifier 100 may suffer a loss due to an insertion loss of the switch S1 that is turned on, an off-capacitance loss of the switch S2 that is turned off, and an off-capacitance loss of the switch S4 that is turned off. In the front end module 1000B of FIG. 3, there are three switches (i.e., S1, S2, and S4) that cause a loss in the RF receiving signal, so the loss can be reduced compared to a typical front end module (see FIG. 15 described below). Due to the reduced loss of the RF receiving signal, the front end module 1000B of FIG. 3 may improve the noise figure. In other words, the front end module 1000B may improve the noise figure by reducing the number of switches connected to the input terminal LNA_IN of the low noise amplifier 100.

FIG. 4B is a diagram showing the operation of the front end module 1000B in the reception bypass mode.

In the reception bypass mode, the switch S1 may be turned off, and the switch S2, the switch S3, and the switch S4 may be turned on. The low noise amplifier 100 and the power amplifier 200 may be set to the off state.

As shown in FIG. 4B, in the reception bypass mode, the RF receiving signal may pass through an RF reception bypass path RFP_BP formed by the antenna terminal ANT, the switch S2, the switch S3, and the receiving terminal RX. That is, the RF receiving signal may be output to the receiving terminal RX through the bypass path that bypasses the low noise amplifier 100. Through this, the RF receiving signal may be output directly to the receiving terminal RX without being amplified by the low noise amplifier 100.

However, even though the switch S1 is turned off, a portion of the RF receiving signal may pass through the switch S1 and leak to the input terminal LNA_IN of the low noise amplifier 100. But because the switch S4 is set to the on state, the portion of the RF receiving signal that may leak can flow to the ground through the switch S4 without leaking to the input terminal LNA_IN of the low noise amplifier 100. Accordingly, an isolation of the RF receiving signal may be improved.

FIG. 4C is a diagram showing the operation of the front end module 10001B in the transmission mode.

In the transmission mode, the switch S2 may be turned on, and the switch S3 may be turned off. Also, the switch S1 may be turned off, and the switch S4 may turned on. The power amplifier 200 may be set to the on state, and the low noise amplifier 100 may be set to the off state.

As shown in FIG. 4C, in the transmission mode, the RF transmitting signal may pass through an RF transmission path RFP_TX formed by the transmitting terminal TX, the power amplifier 200, the switch S2, and the antenna terminal ANT.

When the RF transmission path RFP_TX is formed, the power amplifier 200 amplifies the RF transmitting signal input to the input terminal PA_IN. The amplified RF transmitting signal may be output to the antenna terminal ANT through the switch S2.

However, even if the switch S1 is turned off, a portion of the RF transmitting signal may pass through the switch S1 and leak to the input terminal LNA_IN of the low noise amplifier 100. But because the switch S4 is set to the on state, the portion of the RF transmitting signal that may leak can flow to the ground through the switch S4 without leaking to the input terminal LNA_IN of the low noise amplifier 100. Accordingly, an isolation of the RF transmitting signal may be improved.

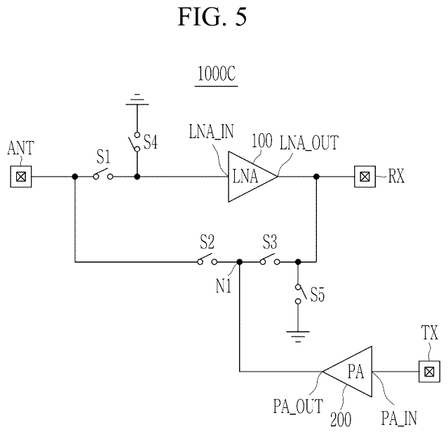

FIG. 5 illustrates a front end module 1000C according to another example.

As shown in FIG. 5, the front end module 1000C may include a low noise amplifier 100, a power amplifier 200, and a plurality of switches S1˜S5. Since the front end module 1000C of FIG. 5 is similar to the front end module 1000B of FIG. 3 except that the switch S5 is added, overlapping descriptions may be omitted.

The plurality of switches S1˜S5 may set the path for the RF receiving signal or set the path for the RF transmitting signal. The connection relationship and operation of the switch S1, the switch S2, the switch S3, and the switch S4 have the same connection relationship and operation as described in FIG. 1 and FIG. 3.

The switch S5 may be connected between the output terminal LNA_OUT of the low noise amplifier 100 and the ground. That is, the switch S5 may be connected between the second terminal of the switch S3 and the ground. The switch S5 may be turned on in the transmission mode. Also, the switch S5 may be turned off in the reception mode and the reception bypass mode.

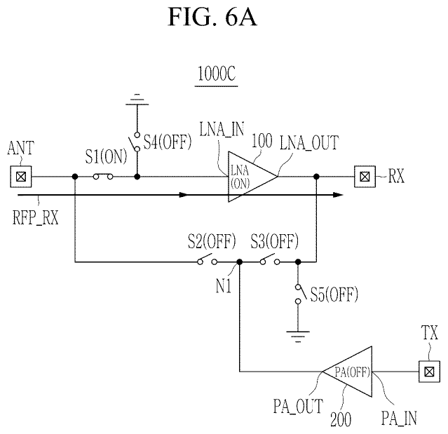

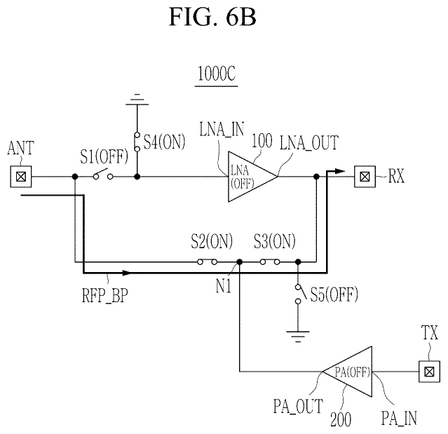

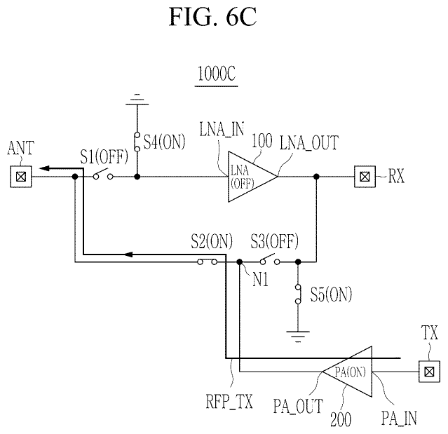

With reference to FIGS. 6A to 6C, the operation of the front end module 1000C in each mode will be described.

FIG. 6A is a diagram showing the operation of the front end module 1000C in the reception mode.

In the reception mode, the switch S1 may be turned on, and the switch S2, the switch S3, the switch S4, and the switch S5 may be turned off. The low noise amplifier 100 may be set to the on state, and the power amplifier 200 may be set to the off state.

As shown in FIG. 6A, in the reception mode, the RF receiving signal may pass through an RF reception path RFP_RX formed by the antenna terminal ANT, the switch S1, the low noise amplifier 100, and the receiving terminal RX.

When the RF reception path RFP_RX is formed, the low noise amplifier 100 amplifies the RF receiving signal input to the input terminal LNA_IN. At this time, the RF receiving signal input to the input terminal LNA_IN of the low noise amplifier 100 may suffer a loss due to the switch S1, the switch S2, and the switch S4. Switches that directly affect the RF receiving signal input to the low noise amplifier 100 may be the switch S1, the switch S2, and the switch S4. In the reception mode, the switch S1 is turned on, and the switch S2 and the switch S4 are turned off. Accordingly, the RF receiving signal input to the low noise amplifier 100 may suffer a loss due to an insertion loss of the switch S1 that is turned on, an off-capacitance loss of the switch S2 that is turned off, and an off-capacitance loss of the switch S4 that is turned off. In the front end module 1000C of FIG. 5, there are three switches (i.e., S1, S2, and S4) that cause a loss in the RF receiving signal, so the loss can be reduced compared to a typical front end module (see FIG. 15 described below). Due to the reduced loss of the RF receiving signal, the front end module 1000C of FIG. 5 may improve the noise figure. In other words, the front end module 1000C may improve the noise figure by reducing the number of switches connected to the input terminal LNA_IN of the low noise amplifier 100.

FIG. 6B is a diagram showing the operation of the front end module 1000C in the reception bypass mode.

In the reception bypass mode, the switch S1 and the switch S5 may be turned off, and the switch S2, the switch S3, and the switch S4 may be turned on. The low noise amplifier 100 and the power amplifier 200 may be set to the off state.

As shown in FIG. 6B, in the reception bypass mode, the RF receiving signal may pass through an RF reception bypass path RFP_BP formed by the antenna terminal ANT, the switch S2, the switch S3, and the receiving terminal RX. That is, the RF receiving signal may be output to the receiving terminal RX through the bypass path that bypasses the low noise amplifier 100. Through this, the RF receiving signal may be output directly to the receiving terminal RX without being amplified by the low noise amplifier 100.

However, even if the switch S1 is turned off, a portion of the RF receiving signal may pass through the switch S1 and leak to the input terminal LNA_IN of the low noise amplifier 100. But because the switch S4 is set to the on state, the portion of the RF receiving signal that may leak can flow to the ground through the switch S4 without leaking to the input terminal LNA_IN of the low noise amplifier 100. Accordingly, an isolation of the RF receiving signal may be improved.

FIG. 6C is a diagram showing the operation of the front end module 1000C in the transmission mode.

In the transmission mode, the switch S2 may be turned on, and the switch S3 may be turned off. Also, the switch S1 may be turned off, and the switch S4 and the switch S5 may turned on. The power amplifier 200 may be set to the on state, and the low noise amplifier 100 may be set to the off state.

As shown in FIG. 6C, in the transmission mode, the RF transmitting signal pass through an RF transmission path RFP_TX formed by the transmitting terminal TX, the power amplifier 200, the switch S2, and the antenna terminal ANT.

When the RF transmission path RFP_TX is formed, the power amplifier 200 amplifies the RF transmitting signal input to the input terminal PA_IN. The amplified RF transmitting signal may be output to the antenna terminal ANT through the switch S2.

However, even if the switch S1 is turned off, a portion of the RF transmitting signal may pass through the switch S1 and leak to the input terminal LNA_IN of the low noise amplifier 100. But because the switch S4 is set to the on state, the portion of the RF transmitting signal that may leak can flow to the ground through the switch S4 without leaking to the input terminal LNA_IN of the low noise amplifier 100. Accordingly, an isolation of the RF transmitting signal may be improved.

Also, even if the switch S3 is turned off, a portion of the RF transmitting signal may pass through the switch S3 and leak to the output terminal LNA_OUT of the low noise amplifier 100. But because the switch S5 is set to the on state, the portion of the RF transmitting signal that may leak can flow to the ground through the switch S5 without leaking to the output terminal LNA_OUT of the low noise amplifier 100. Accordingly, an isolation of the RF transmitting signal may be improved.

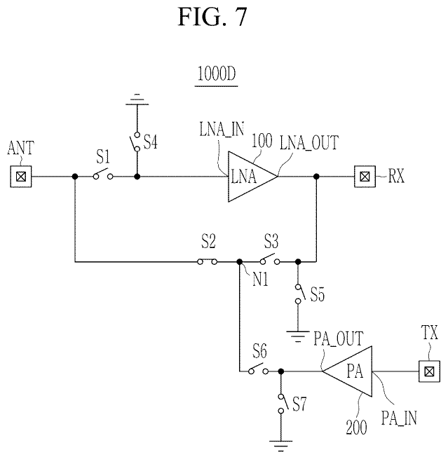

FIG. 7 illustrates a front end module 1000D according to another example.

As shown in FIG. 7, the front end module 1000D may include a low noise amplifier 100, a power amplifier 200, and a plurality of switches S1˜S7. Since the front end module 1000D of FIG. 7 is similar to the front end module 1000C of FIG. 5 except that the switch S6 and the switch S7 are added, overlapping descriptions may be omitted.

The plurality of switches S1˜S7 may set the path for the RF receiving signal or set the path for the RF transmitting signal. Here, the connection relationship and operation of the switch S1, the switch S2, the switch S3, the switch S4, and the switch S5 have the same connection relationship and operation as described in FIG. 1, FIG. 3, and FIG. 5.

The switch S6 may be connected between the node where the switch S2 and the switch S3 are connected (that is, the first node N1) and the output terminal PA_OUT of the power amplifier 200. That is, a first terminal of the switch S6 may be connected to the second terminal of the switch S2 and the first terminal of the switch S3, and a second terminal of the switch S6 may be connected to the output terminal PA_OUT of the power amplifier 200. The switch S6 may be turned on in the transmission mode, and may be turned off in the reception mode and the reception bypass mode.

The switch S7 may be connected between the second terminal of the switch S6 and the ground. That is, the switch S7 may be connected between the output terminal PA_OUT of the power amplifier 200 and the ground. The switch S7 may be turned on in the reception mode and the reception bypass mode, and may be turned off in the transmission mode. The switch S7 is a shunt switch and operates opposite to the switching operation of the switch S6, thereby improving isolation.

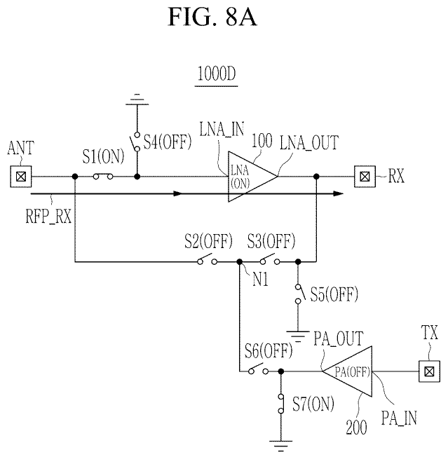

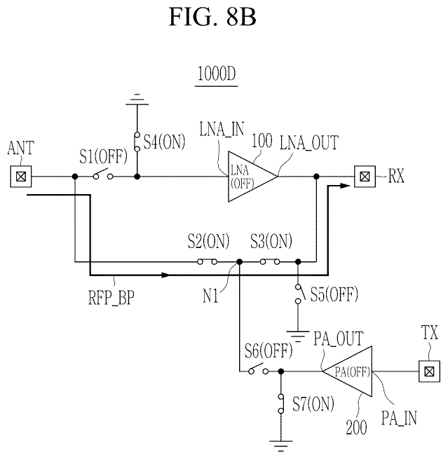

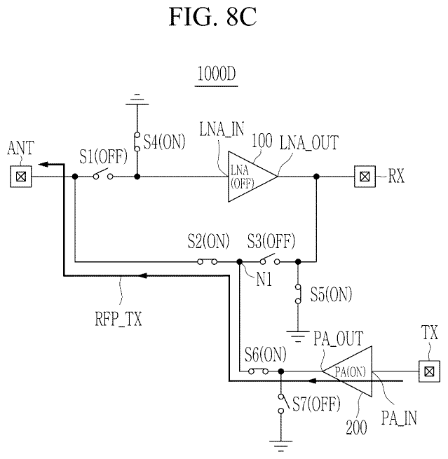

With reference to FIGS. 8A to 8C, the operation of the front end module 1000D in each mode will be described.

FIG. 8A is a diagram showing the operation of the front end module 1000D in the reception mode.

In the reception mode, the switch S1 and the switch S7 may be turned on, and the switch S2, the switch S3, the switch S4, the switch S5, and the switch S6 may be turned off. The low noise amplifier 100 may be set to the on state, and the power amplifier 200 may be set to the off state.

As shown in FIG. 8A, in the reception mode, the RF receiving signal may pass through an RF reception path RFP_RX formed by the antenna terminal ANT, the switch S1, the low noise amplifier 100, and the receiving terminal RX.

When the RF reception path RFP_RX is formed, the low noise amplifier 100 amplifies the RF receiving signal input to the input terminal LNA_IN. At this time, the RF receiving signal input to the input terminal LNA_IN of the low noise amplifier 100 may suffer a loss due to the switch S1, the switch S2, and the switch S4. Switches that directly affect the RF receiving signal input to the low noise amplifier 100 may be the switch S1, the switch S2, and the switch S4. In the reception mode, the switch S1 is turned on, and the switch S2 and the switch S4 are turned off. Accordingly, the RF receiving signal input to the low noise amplifier 100 may suffer a loss due to an insertion loss of the switch S1 that is turned on, an off-capacitance loss of the switch S2 that is turned off, and an off-capacitance loss of the switch S4 that is turned off. In the front end module 1000D of FIG. 7, there are three switches (i.e., S1, S2, and S4) that cause a loss in the RF receiving signal, so the loss can be reduced compared to a typical front end module (FIG. 15 below). Due to the reduced loss of the RF receiving signal, the front end module 1000D of FIG. 7 may improve the noise figure. In other words, the front end module 1000D may improve the noise figure by reducing the number of switches connected to the input terminal LNA_IN of the low noise amplifier 100.

FIG. 8B is a diagram showing the operation of the front end module 1000D in the reception bypass mode.

In the reception bypass mode, the switch S1, the switch S5, and the switch S6 may be turned off, and the switch S2, the switch S3, the switch S4, and the switch S7 may be turned on. The low noise amplifier 100 and the power amplifier 200 may be set to the off state.

As shown in FIG. 8B, in the reception bypass mode, the RF receiving signal may pass through an RF reception bypass path RFP_BP formed by the antenna terminal ANT, the switch S2, the switch S3, and the receiving terminal RX. That is, the RF receiving signal may be output to the receiving terminal RX through the bypass path that bypasses the low noise amplifier 100. Through this, the RF receiving signal may be output directly to the receiving terminal RX without being amplified by the low noise amplifier 100.

However, even if the switch S1 is turned off, a portion of the RF receiving signal may pass through the switch S1 and leak to the input terminal LNA_IN of the low noise amplifier 100. But because the switch S4 is set to the on state, the portion of the RF receiving signal that may leak can flow to the ground through the switch S4 without leaking to the input terminal LNA_IN of the low noise amplifier 100. Accordingly, an isolation of the RF receiving signal may be improved.

The RF receiving signal transmitted through the RF reception bypass path RFP_BP may suffer a loss depending on the configuration of the output stage of the power amplifier 200. Although not shown in FIG. 7, the output stage of the power amplifier 200 may generally have a predetermined element for impedance matching, which may cause a loss of the RF receiving signal. To prevent this, the front end module 1000D further includes the switch S6 and the switch S7.

However, even if the switch S6 is turned off, a portion of the RF receiving signal may pass through the switch S6 and leak to the output terminal PA_OUT of the power amplifier 200. But because the switch S7 is set to the on state, the portion of the RF receiving signal that may leak can flow to the ground through the switch S7 without leaking to the output terminal PA_OUT of the power amplifier 200. Accordingly, an isolation of the RF receiving signal may be improved.

FIG. 8C is a diagram showing the operation of the front end module 1000D in the transmission mode.

In the transmission mode, the switch S2 and the switch S6 may be turned on, and the switch S3 may be turned off. Also, the switch S1 and the switch S7 may be turned off, and the switch S4 and the switch S5 may turned on. The power amplifier 200 may be set to the on state, and the low noise amplifier 100 may be set to the off state.

As shown in FIG. 8C, in the transmission mode, the RF transmitting signal may pass through an RF transmission path RFP_TX formed by the transmitting terminal TX, the power amplifier 200, the switch S6, the switch S2, and the antenna terminal ANT.

When the RF transmission path RFP_TX is formed, the power amplifier 200 amplifies the RF transmitting signal input to the input terminal PA_IN. The amplified RF transmitting signal may be output to the antenna terminal ANT through the switch S6 and the switch S2.

However, even if the switch S1 is turned off, a portion of the RF transmitting signal may pass through the switch S1 and leak to the input terminal LNA_IN of the low noise amplifier 100. But because the switch S4 is set to the on state, the portion of the RF transmitting signal that may leak can flow to the ground through the switch S4 without leaking to the input terminal LNA_IN of the low noise amplifier 100. Accordingly, an isolation of the RF transmitting signal may be improved.

Also, even if the switch S3 is turned off, a portion of the RF transmitting signal may pass through the switch S3 and leak to the output terminal LNA_OUT of the low noise amplifier 100. But because the switch S5 is set to the on state, the portion of the RF transmitting signal that may leak can flow to the ground through the switch S5 without leaking to the output terminal LNA_OUT of the low noise amplifier 100. Accordingly, an isolation of the RF transmitting signal may be improved.

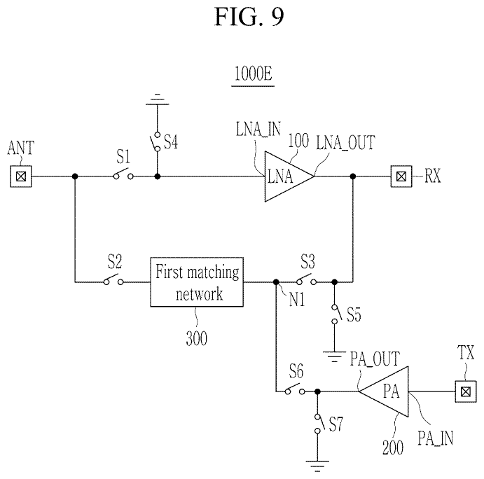

FIG. 9 illustrates a front end module 1000E according to another example.

As shown in FIG. 9, the front end module 1000E may include a low noise amplifier 100, a power amplifier 200, a first matching network 300, and a plurality of switches S1˜S7. Since the front end module 1000E of FIG. 9 is similar to the front end module 1000D of FIG. 7 except that the first matching network 300 is added, overlapping descriptions may be omitted.

The first matching network 300 may be connected between the switch S2 and the switch S3. That is, a first terminal of the first matching network 300 may be connected to the second terminal of the switch S2, and a second terminal of the first matching network 300 may be connected to the first terminal of the switch S3 so that the first matching network 300 may be connected between the second terminal of the switch S2 and the first terminal of the switch S6. The first matching network 300 may include one or more elements selected from a capacitor, an inductor, and a resistor. In the reception bypass mode, the first matching network 300 may perform a frequency matching operation. Also, when the RF receiving signal is large in the reception bypass mode, the first matching network 300 may serve to attenuate the RF receiving signal. In the transmission mode, the first matching network 300 may serve to match the output impedance of the power amplifier 200.

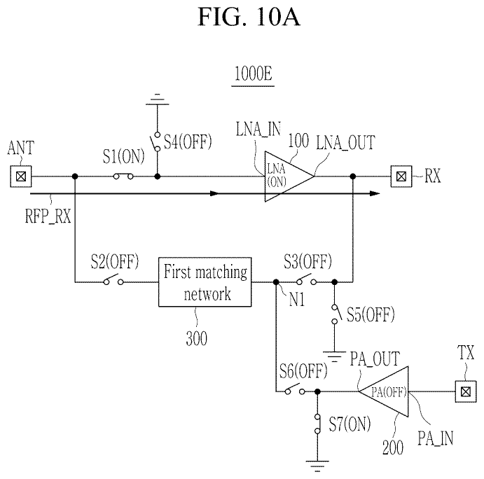

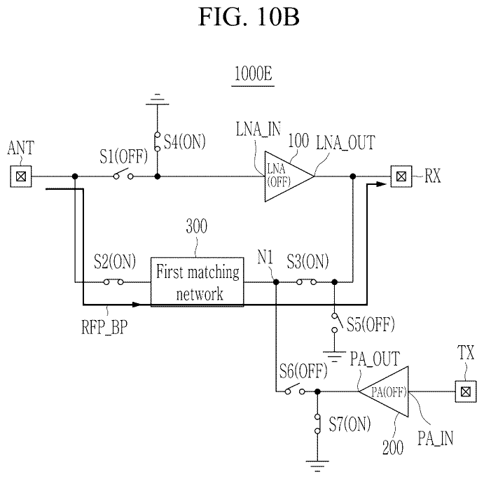

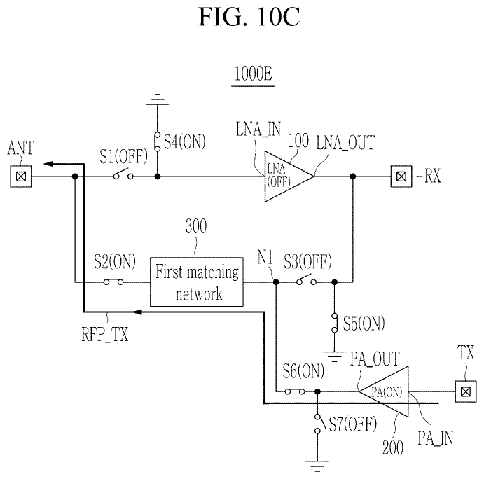

With reference to FIGS. 10A to 10C, the operation of the front end module 1000E in each mode will be described.

FIG. 10A is a diagram showing the operation of the front end module 1000E in the reception mode.

In the reception mode, the switch S1 and the switch S7 may be turned on, and the switch S2, the switch S3, the switch S4, the switch S5, and the switch S6 may be turned off.

The low noise amplifier 100 may be set to the on state, and the power amplifier 200 may be set to the off state.

As shown in FIG. 10A, in the reception mode, the RF receiving signal may pass through an RF reception path RFP_RX formed by the antenna terminal ANT, the switch S1, the low noise amplifier 100, and the receiving terminal RX.

When the RF reception path RFP_RX is formed, the low noise amplifier 100 amplifies the RF receiving signal input to the input terminal LNA_IN. At this time, the RF receiving signal input to the input terminal LNA_IN of the low noise amplifier 100 may suffer a loss due to the switch S1, the switch S2, and the switch S4. Thus, in the front end module 1000E of FIG. 9, there are three switches (i.e., S1, S2, and S4) that cause a loss in the RF receiving signal, so the loss can be reduced compared to a typical front end module (see FIG. 15 described below). Due to the reduced loss of the RF receiving signal, the front end module 1000E of FIG. 9 may improve the noise figure. In other words, the front end module 1000E may improve the noise figure by reducing the number of switches connected to the input terminal LNA_IN of the low noise amplifier 100.

FIG. 10B is a diagram showing the operation of the front end module 1000E in the reception bypass mode.

In the reception bypass mode, the switch S1, the switch S5, and the switch S6 may be turned off, and the switch S2, the switch S3, the switch S4, and the switch S7 may be turned on. The low noise amplifier 100 and the power amplifier 200 may be set to the off state.

As shown in FIG. 10B, in the reception bypass mode, the RF receiving signal may pass through an RF reception bypass path RFP_BP formed by the antenna terminal ANT, the switch S2, the first matching network 300, the switch S3, and the receiving terminal RX. That is, the RF receiving signal may be output to the receiving terminal RX through the bypass path that bypasses the low noise amplifier 100. Through this, the RF receiving signal may be output directly to the receiving terminal RX without being amplified by the low noise amplifier 100.

In the reception bypass mode, the first matching network 300 is positioned in the RF reception bypass path RFP_BP. Accordingly, the first matching network 300 may perform a frequency matching operation. When the RF receiving signal is large, the first matching network 300 may serve to attenuate the RF receiving signal.

FIG. 10C is a diagram showing the operation of the front end module 1000E in the transmission mode.

In the transmission mode, the switch S2 and the switch S6 may be turned on, and the switch S3 may be turned off. Also, the switch S1 and the switch S7 may be turned off, and the switch S4 and the switch S5 may turned on. The power amplifier 200 may be set to the on state, and the low noise amplifier 100 may be set to the off state.

As shown in FIG. 10C, in the transmission mode, the RF transmitting signal may pass through an RF transmission path RFP_TX formed by the transmitting terminal TX, the power amplifier 200, the switch S6, the first matching network 300, the switch S2, and the antenna terminal ANT.

When the RF transmission path RFP_TX is formed, the power amplifier 200 amplifies the RF transmitting signal input to the input terminal PA_IN. The amplified RF transmitting signal may be output to the antenna terminal ANT through the switch S6, the first matching network 300, and the switch S2.

In the transmission mode, the first matching network 300 is connected to the output terminal PA_OUT of the power amplifier 200. Accordingly, the first matching network 300 may serve to match the output impedance of the power amplifier 200.

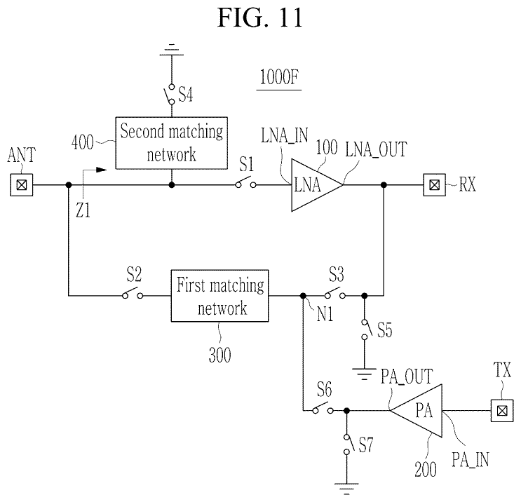

FIG. 11 illustrates a front end module 1000F according to another example.

As shown in FIG. 11, the front end module 1000F may include a low noise amplifier 100, a power amplifier 200, a first matching network 300, a second matching network 400, and a plurality of switches S1˜S7. Since the front end module 1000F of FIG. 11 is similar to the front end module 1000E of FIG. 9 except that the second matching network 400 is added, overlapping descriptions may be omitted.

The switch S1 may be connected between the antenna terminal ANT and the input terminal LNA_IN of the low noise amplifier 100. That is, a first terminal of the switch S1 may be connected to the antenna terminal ANT, and a second terminal of the switch S1 may be connected to the input terminal LNA_IN of the low noise amplifier 100. The switch S1 may be turned on in the reception mode and may transmit the RF receiving signal received from the antenna terminal ANT to the input terminal LNA_IN of the low noise amplifier 100. Also, the switch S1 may be turned off in the reception bypass mode and the transmission mode.

A first terminal of the second matching network 400 may be connected to the antenna terminal ANT and the first terminal of the switch S1. The switch S4 may be connected between a second terminal of the second matching network 400 and the ground. That is, a first terminal of the switch S4 may be connected to the second terminal of the second matching network 400, and a second terminal of the switch S4 may be connected to the ground. The switch S4 may be turned on in the reception bypass mode and the transmission mode. The switch S4 may be turned off in the reception mode. When the switch S4 is turned on, the second terminal of the second matching network 400 is connected to the ground through the switch S4, and the second matching network 400 may provide a predetermined impedance.

The second matching network 400 may include one or more elements selected from a capacitor, an inductor, and a resistor. The switch S4 is turned on in the reception bypass mode and the transmission mode, and the second matching network 400 may serve to increase an impedance Z1 seen from the antenna terminal ANT to the input terminal LNA_IN of the low noise amplifier 100. Accordingly, the second matching network 400 can reduce a portion of the RF receiving signal that may leak to the input terminal LNA_IN of the low noise amplifier 100 in the reception bypass mode. Additionally, the second matching network 400 can reduce a portion of the RF transmitting signal that may leak to the input terminal LNA_IN of the low noise amplifier 100 in the transmission mode.

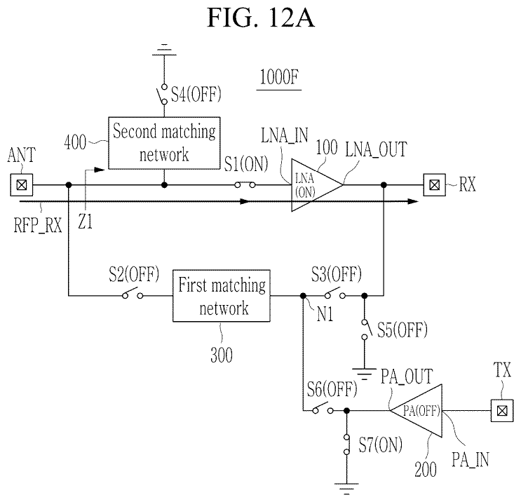

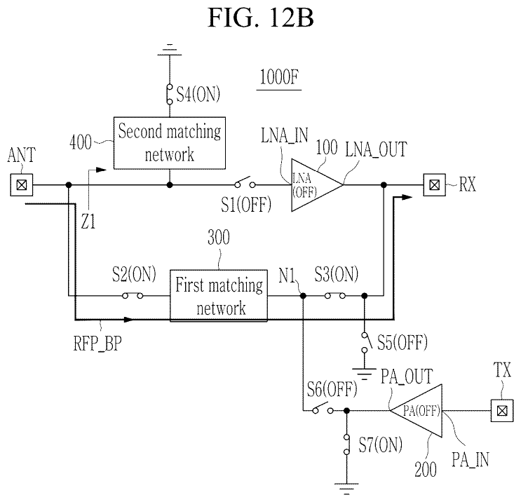

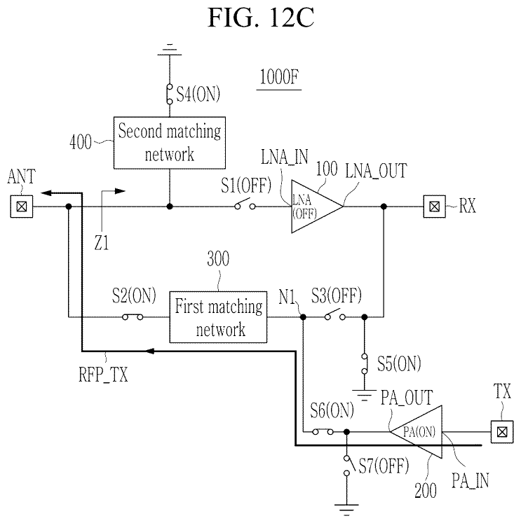

With reference to FIGS. 12A to 12C, the operation of the front end module 1000F in each mode will be described.

FIG. 12A is a diagram showing the operation of the front end module 1000F in the reception mode.

In the reception mode, the switch S1 and the switch S7 may be turned on, and the switch S2, the switch S3, the switch S4, the switch S5, and the switch S6 may be turned off. The low noise amplifier 100 may be set to the on state, and the power amplifier 200 may be set to the off state.

As shown in FIG. 12A, in the reception mode, the RF receiving signal may pass through an RF reception path RFP_RX formed by the antenna terminal ANT, the switch S1, the low noise amplifier 100, and the receiving terminal RX.

When the RF reception path RFP_RX is formed, the low noise amplifier 100 amplifies the RF receiving signal input to the input terminal LNA_IN. At this time, the RF receiving signal input to the input terminal LNA_IN of the low noise amplifier 100 may suffer a loss due to the switch S1, the switch S2, and the switch S4. In the front end module 1000F of FIG. 11, there are three switches (i.e., S1, S2, and S4) that cause a loss in the RF receiving signal, so the loss can be reduced compared to a typical front end module (see FIG. 15 described below). Due to the reduced loss of the RF receiving signal, the front end module 1000F of FIG. 11 may improve the noise figure. In other words, the front end module 1000F may improve the noise figure by reducing the number of switches connected to the input terminal LNA_IN of the low noise amplifier 100.

FIG. 12B is a diagram showing the operation of the front end module 1000F in the reception bypass mode.

In the reception bypass mode, the switch S1, the switch S5, and the switch S6 may be turned off, and the switch S2, the switch S3, the switch S4, and the switch S7 may be turned on. The low noise amplifier 100 and the power amplifier 200 may be set to the off state.

As shown in FIG. 12B, in the reception bypass mode, the RF receiving signal may pass through an RF reception bypass path RFP_BP formed by the antenna terminal ANT, the switch S2, the first matching network 300, the switch S3, and the receiving terminal RX. That is, the RF receiving signal may be output to the receiving terminal RX through the bypass path that bypasses the low noise amplifier 100. Through this, the RF receiving signal may be output directly to the receiving terminal RX without being amplified by the low noise amplifier 100.

In the reception bypass mode, the first matching network 300 is positioned in the RF reception bypass path RFP_BP. Accordingly, the first matching network 300 may perform a frequency matching operation. When the RF receiving signal is large, the first matching network 300 may serve to attenuate the RF receiving signal.

In the reception bypass mode, the switch S4 is turned on, and thus the second matching network 400 is connected to the ground. At this time, the impedance Z1 seen from the antenna terminal ANT to the input terminal LNA_IN of the low noise amplifier 100 increases. However, even if the switch S1 is turned off, a portion of the RF receiving signal may pass through the switch S1 and leak to the input terminal LNA_IN of the low noise amplifier 100. Due to the second matching network 400, the portion of the RF receiving signal that may leak to the input terminal LNA_IN of the low noise amplifier 100 can be reduced.

FIG. 12C is a diagram showing the operation of the front end module 1000F in the transmission mode.

In the transmission mode, the switch S2 and the switch S6 may be turned on, and the switch S3 may be turned off. Also, the switch S1 and the switch S7 may be turned off, and the switch S4 and the switch S5 may turned on. The power amplifier 200 may be set to the on state, and the low noise amplifier 100 may be set to the off state.

As shown in FIG. 12C, in the transmission mode, the RF transmitting signal may pass through an RF transmission path RFP_TX formed by the transmitting terminal TX, the power amplifier 200, the switch S6, the first matching network 300, the switch S2, and the antenna terminal ANT.

When the RF transmission path RFP_TX is formed, the power amplifier 200 amplifies the RF transmitting signal input to the input terminal PA_IN. The amplified RF transmitting signal may be output to the antenna terminal ANT through the switch S6, the first matching network 300, and the switch S2.

In the transmission mode, the first matching network 300 is connected to the output terminal PA_OUT of the power amplifier 200. Accordingly, the first matching network 300 may serve to match the output impedance of the power amplifier 200.

In the transmission mode, the switch S4 is turned on, and thus the second matching network 400 is connected to the ground. At this time, the impedance Z1 seen from the antenna terminal ANT to the input terminal LNA_IN of the low noise amplifier 100 increases. However, even if the switch S1 is turned off, a portion of the RF transmitting signal may pass through the switch S1 and leak to the input terminal LNA_IN of the low noise amplifier 100. Due to the second matching network 400, the portion of the RF transmitting signal that may leak to the input terminal LNA_IN of the low noise amplifier 100 can be reduced. Accordingly, an operating efficiency of the power amplifier 200 can be increased.

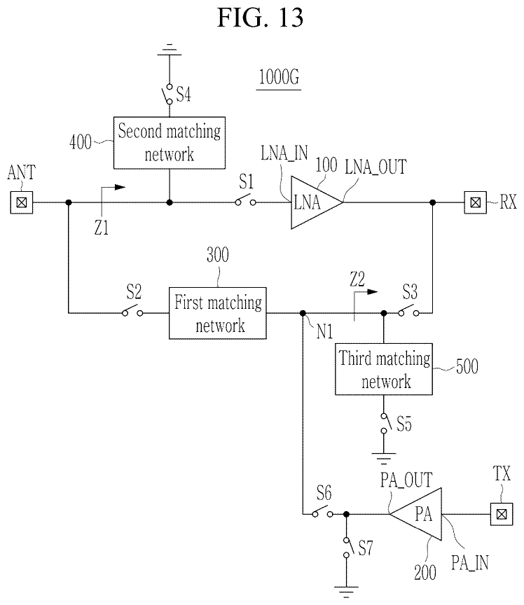

FIG. 13 illustrates a front end module 1000G according to another example.

As shown in FIG. 13, the front end module 1000G may include a low noise amplifier 100, a power amplifier 200, a first matching network 300, a second matching network 400, a third matching network 500, and a plurality of switches S1˜S7. Since the front end module 1000G of FIG. 13 is similar to the front end module 1000F of FIG. 11 except that the third matching network 500 is added, overlapping descriptions may be omitted.

The switch S3 may be connected between the second terminal of the first matching network 300 and the output terminal LNA_OUT of the low noise amplifier 100. That is, the first terminal of the switch S3 may be connected to the second terminal of the first matching network 300, and the second terminal of the switch S3 may be connected to the output terminal LNA_OUT of the low noise amplifier 100. Also, the first terminal of the switch S3 may be connected to the first terminal of the switch S6.

A first terminal of the third matching network 500 may be connected to the first terminal of the switch S3, the first terminal of the switch S6, and the second terminal of the first matching network 300. That is, the first terminal of the third matching network 500 may be connected to the first node N1. Additionally, the switch S5 may be connected between a second terminal of the third matching network 500 and the ground. The switch S5 may be turned on in the transmission mode, and turned off in the reception mode and the reception bypass mode. When the switch S5 is turned on, the second terminal of the third matching network 500 is connected to the ground through the switch S5, and the third matching network 500 may provide a predetermined impedance.

The third matching network 500 may include one or more elements selected from a capacitor, an inductor, and a resistor. The switch S5 is turned on in the transmission mode, and the third matching network 500 may serve to increase an impedance Z2 seen from the first terminal of the switch S6 (i.e., the first node N1) to the output terminal LNA_OUT of the low noise amplifier 100. Accordingly, the third matching network 500 can reduce a leakage of the RF transmitting signal to the output terminal LNA_OUT of the low noise amplifier 100 in the transmission mode.

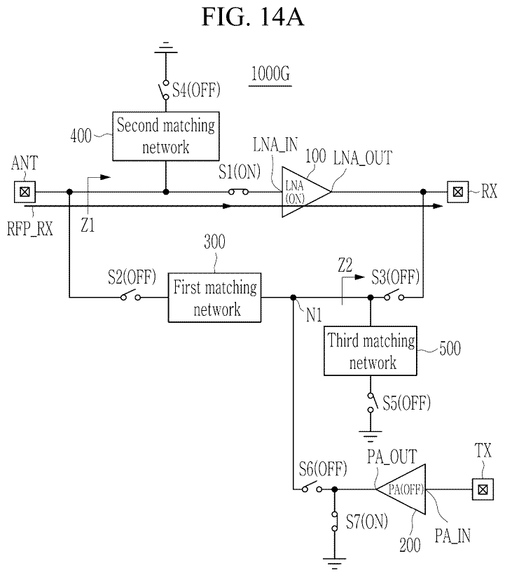

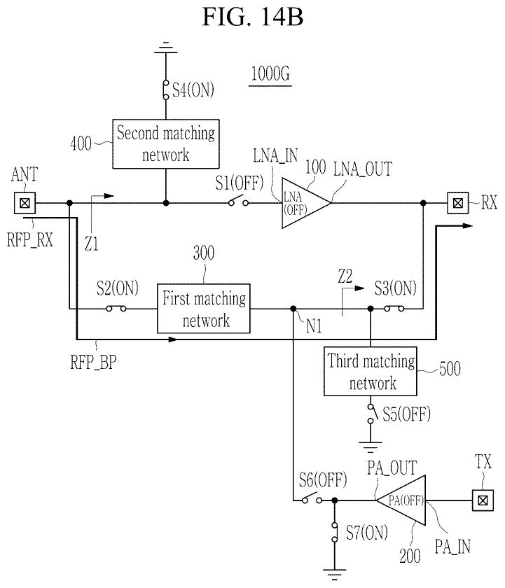

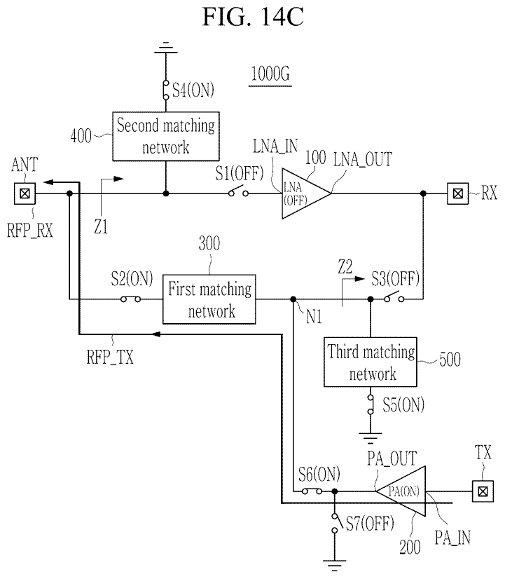

With reference to FIGS. 14A to 14C, the operation of the front end module 1000G in each mode will be described.

FIG. 14A is a diagram showing the operation of the front end module 1000G in the reception mode.

In the reception mode, the switch S1 and the switch S7 may be turned on, and the switch S2, the switch S3, the switch S4, the switch S5, and the switch S6 may be turned off. The low noise amplifier 100 may be set to the on state, and the power amplifier 200 may be set to the off state.

As shown in FIG. 14A, in the reception mode, the RF receiving signal may pass through an RF reception path RFP_RX formed by the antenna terminal ANT, the switch S1, the low noise amplifier 100, and the receiving terminal RX.

When the RF reception path RFP_RX is formed, the low noise amplifier 100 amplifies the RF receiving signal input to the input terminal LNA_IN. At this time, the RF receiving signal input to the input terminal LNA_IN of the low noise amplifier 100 may suffer a loss due to the switch S1, the switch S2, and the switch S4. In the front end module 1000G of FIG. 13, there are three switches (i.e., S1, S2, and S4) that cause a loss in the RF receiving signal, so the loss can be reduced compared to a typical front end module (see FIG. 15 described below). Due to the reduced loss of the RF receiving signal, the front end module 1000G of FIG. 13 may improve the noise figure. In other words, the front end module 1000G may improve the noise figure by reducing the number of switches connected to the input terminal LNA_IN of the low noise amplifier 100.

FIG. 14B is a diagram showing the operation of the front end module 1000G in the reception bypass mode.

In the reception bypass mode, the switch S1, the switch S5 and the switch S6 may be turned off, and the switch S2, the switch S3, the switch S4, and the switch S7 may be turned on. The low noise amplifier 100 and the power amplifier 200 may be set to the off state.

As shown in FIG. 14B, in the reception bypass mode, the RF receiving signal may pass through an RF reception bypass path RFP_BP formed by the antenna terminal ANT, the switch S2, the first matching network 300, the switch S3, and the receiving terminal RX. That is, the RF receiving signal may be output to the receiving terminal RX through the bypass path that bypasses the low noise amplifier 100. Through this, the RF receiving signal may be output directly to the receiving terminal RX without being amplified by the low noise amplifier 100.

In the reception bypass mode, the first matching network 300 is positioned in the RF reception bypass path RFP_BP. Accordingly, the first matching network 300 may perform a frequency matching operation. When the RF receiving signal is large, the first matching network 300 may serve to attenuate the RF receiving signal.

In the reception bypass mode, the switch S4 is turned on, and thus the second matching network 400 is connected to the ground. At this time, the impedance Z1 seen from the antenna terminal ANT to the input terminal LNA_IN of the low noise amplifier 100 increases. Even if the switch S1 is turned off, a portion of the RF receiving signal may leak through the switch S1. Due to the second matching network 400, the portion of the RF receiving signal that may leak to the input terminal LNA_IN of the low noise amplifier 100 can be reduced.

FIG. 14C is a diagram showing the operation of the front end module 1000G in the transmission mode.

In the transmission mode, the switch S2 and the switch S6 may be turned on, and the switch S3 may be turned off. Also, the switch S1 and the switch S7 may be turned off, and the switch S4 and the switch S5 may turned on. The power amplifier 200 may be set to the on state, and the low noise amplifier 100 may be set to the off state.

As shown in FIG. 14C, in the transmission mode, the RF transmitting signal may pass through an RF transmission path RFP_TX formed by the transmitting terminal TX, the power amplifier 200, the switch S6, the first matching network 300, the switch S2, and the antenna terminal ANT.

When the RF transmission path RFP_TX is formed, the power amplifier 200 amplifies the RF transmitting signal input to the input terminal PA_IN. The amplified RF transmitting signal may be output to the antenna terminal ANT through the switch S6, the first matching network 300, and the switch S2.

In the transmission mode, the first matching network 300 is connected to the output terminal PA_OUT of the power amplifier 200. Accordingly, the first matching network 300 may serve to match the output impedance of the power amplifier 200.

In the transmission mode, the switch S4 is turned on, and thus the second matching network 400 is connected to the ground. At this time, the impedance Z1 seen from the antenna terminal ANT to the input terminal LNA_IN of the low noise amplifier 100 increases. Even if the switch S1 is turned off, a portion of the RF transmitting signal may pass through the switch S1 and leak to the input terminal LNA_IN of the low noise amplifier 100. Due to the second matching network 400, the portion of the RF transmitting signal that may leak to the input terminal LNA_IN of the low noise amplifier 100 can be reduced. Accordingly, an operating efficiency of the power amplifier 200 can be increased.

In the transmission mode, the switch S5 is turned on, and thus the third matching network 500 is connected to the ground. At this time, the impedance Z2 seen from the first terminal of the switch S6 to the output terminal LNA_OUT of the low noise amplifier 100 increases. Even if the switch S3 is turned off, a portion of the RF transmitting signal may pass through the switch S3 and leak to the output terminal LNA_OUT of the low noise amplifier 100. Due to the third matching network 500, the portion of the RF transmitting signal that may leak to the output terminal LNA_OUT of the low noise amplifier 100 can be reduced. Accordingly, an operating efficiency of the power amplifier 200 can be increased.

FIG. 15 illustrates a front-end module 2000 according to a comparative example. That is, FIG. 15 is a diagram showing a typical front-end module.

As shown in FIG. 15, the front end module 2000 may include a low noise amplifier 100, a power amplifier 200, and a plurality of switches S8˜S12.

The plurality of switches S8˜S12 may set the path for the RF receiving signal or set the path for the RF transmitting signal.

In the reception mode, the switch S8 and the switch S12 are turned on, and the switch S9, the switch S10, and the switch S11 are turned off. The low noise amplifier 100 may be set to the on state, and the power amplifier 200 may be set to the off state. The RF receiving signal may pass through an RF reception path formed by the antenna terminal ANT, the switch S8, the low noise amplifier 100, and the receiving terminal RX. When the RF reception path is formed, the RF receiving signal input to the input terminal of the low noise amplifier 100 suffers a loss due to the switch S8, the switch S9, the switch S10, and the switch S11. The switches that directly affect the RF receiving signal input to the low noise amplifier 100 may be the switch S8, the switch S9, the switch S10, and the switch S11. The RF receiving signal input to the low noise amplifier 100 may suffer a loss due to an insertion loss of the switch S8 that is turned on, and an off-capacitance loss of the switches S9, S10, and S11 that are turned off.

In the front end module 200 of FIG. 15, there are four switches (i.e., S8, S9, S10, and S11) that cause a loss in the RF receiving signal

As explained in FIG. 1, the switches that cause a loss in the RF receiving signal in the front end module 1000A of FIG. 1 are the two switches S1 and S2. Accordingly, the loss in the RF receiving signal in the front end module 1000A of FIG. 1 can be reduced compared to the loss in the RF receiving signal in the front end module 2000 of FIG. 15.

As described above, in the front end module 1000B of FIG. 3, the front end module 1000C of FIG. 5, the front end module 1000D of FIG. 7, the front end module 1000E of FIG. 9, the front end module 1000F of FIG. 11, and the front end module 1000G of FIG. 13, the switches that cause a loss in the RF receiving signal are the three switches S1, S2, and S4. Accordingly, the loss in the RF receiving signal in the front end module 1000B of FIG. 3, the front end module 1000C of FIG. 5, the front end module 1000D of FIG. 7, the front end module 1000E of FIG. 9, the front end module 1000F of FIG. 11, and the front-end module 1000G of FIG. 13 can be reduced compared to the loss in the RF receiving signal in the front end module 2000 of FIG. 15.

In the reception bypass mode, the switch S8, the switch S9, and the switch S12 are turned on, and the switch S10 and the switch S11 are turned off. The low noise amplifier 100 and the power amplifier 200 may be set to the off state. The RF receiving signal may pass through an RF reception bypass path formed by the antenna terminal ANT, the switch S8, the switch S9, and the receiving terminal RX.

In the transmission mode, the switch S11 and the switch S10 are turned on, and the switch S8, the switch S9, and the switch S12 are turned off. The power amplifier 200 may be set to the on state, and the low noise amplifier 100 may be set to the off state. The RF transmitting signal may pass through an RF transmission path formed by the transmitting terminal TX, the power amplifier 200, the switch S11, and the antenna terminal ANT.

As described above, according to at least one aspect, by reducing the number of switches that cause a loss in the RF receiving signal, the noise figure may be improved.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A front end module comprising:
a low noise amplifier configured to amplify a receiving signal;
a power amplifier configured to amplify a transmitting signal;
a first switch positioned in a first path that bypasses the low noise amplifier and configured to form the first path; and
a second switch positioned in the first path, connected to the first switch at a first node in the first path, and configured to form the first path together with the first switch,
wherein an output terminal of the power amplifier is connected to the first node.

2. The front end module of claim 1, wherein in a reception bypass mode, the first switch and the second switch are further configured to be turned on to form the first path to enable the receiving signal to pass through the first path formed by the first switch and the second switch.

3. The front end module of claim 2, wherein in a transmission mode, the first switch is further configured to be turned on and the second switch is further configured to be turned off to enable the transmitting signal to pass through a transmission path formed by the power amplifier and the first switch.

4. The front end module of claim 1, further comprising:
an antenna terminal configured to receive the receiving signal; and
a third switch connected between the antenna terminal and an input terminal of the low noise amplifier.

5. The front end module of claim 4, wherein in a reception mode, the third switch is configured to be turned on and the first switch and the second switch are further configured to be turned off to enable the receiving signal to pass through a reception path formed by the antenna terminal, the third switch, and the low noise amplifier.

6. The front end module of claim 4, wherein in a reception bypass mode, the first switch and the second switch are further configured to be turned on and the third switch is configured to be turned off.

7. The front end module of claim 6, further comprising a fourth switch connected between the input terminal of the low noise amplifier and a ground,
wherein the fourth switch is configured to be turned on in the reception bypass mode.

8. The front end module of claim 6, further comprising:
a fourth switch connected between the first node and the output terminal of the power amplifier; and
a fifth switch connected between the output terminal of the power amplifier and a ground,
wherein in the reception bypass mode, the fourth switch is configured to be turned off and the fifth switch is configured to be turned on.

9. The front end module of claim 6, further comprising:
a first matching network comprising a first terminal connected to the antenna terminal; and
a fourth switch connected between a second terminal of the first matching network and a ground,
wherein the fourth switch is configured to be turned on in the reception bypass mode.

10. The front end module of claim 4, wherein in a transmission mode, the first switch is further configured to be turned on and the second switch and the third switch are further configured turned off to enable the transmitting signal to pass through a transmission path formed by the power amplifier, the first switch, and the antenna terminal.

11. The front end module of claim 10, further comprising a fourth switch connected between an output terminal of the low noise amplifier and a ground,
wherein the fourth switch is configured to be turned on in the reception mode.

12. The front end module of claim 10, further comprising:
a first matching network comprising a first terminal connected to the first node; and
a fourth switch connected between a second terminal of the first matching network and a ground,
wherein the fourth switch is configured to turned on in the transmission mode.

13. The front end module of claim 1, further comprising a first matching network positioned in the first path between the first switch and the second switch.

14. The front end module of claim 13, wherein in a reception bypass mode, the first switch and the second switch are further configured to be turned on to enable the receiving signal to pass through the first path formed by the first switch, the first matching network, and the second switch.

15. The front end module of claim 14, wherein in a transmission mode, the first switch is further configured to turned on and the second switch is further configured to be turned off to enable the transmitting signal to pass through a transmission path formed by the power amplifier, the first matching network, and the first switch.

16. An operating method of a front end module, the front end module comprising an antenna terminal, a receiving terminal, a transmitting terminal, a low noise amplifier comprising an input terminal connected to the antenna terminal and an output terminal connected to the receiving terminal, a first switch connected between the antenna terminal and a node, a second switch connected between the node and the receiving terminal, and a power amplifier comprising an input terminal connected to the transmitting terminal and an output terminal connected to the node, the operating method comprising:
in a first mode, turning off the first switch and the second switch to enable the low noise amplifier to amplify a first receiving signal input from the antenna terminal and output the amplified first receiving signal from the receiving terminal;
in a second mode, turning on the first switch and the second switch to enable a second receiving signal input from the antenna terminal to bypass the low noise amplifier and be output from the receiving terminal; and
in a third mode, turning on the first switch and turning off the second switch to enable the power amplifier to amplify a transmitting signal input from the transmitting terminal and output the amplified transmitting signal from the antenna terminal.

17. The operating method of claim 16, wherein in the second mode, the second receiving signal passes through a reception bypass path formed by the antenna terminal, the first switch, the second switch, and the transmission terminal.

18. The operating method of claim 16, wherein in the third mode, the transmitting signal passes through a transmission path formed by the transmitting terminal, the power amplifier, the first switch, and the antenna terminal.

19. The operating method of claim 16, wherein the front end module further comprises a third switch connected between the antenna terminal and the input terminal of the low noise amplifier, and the operating method further comprises:
in the first mode, turning on the third switch while the first switch and the second switch are turned off so that the first receiving signal passes through a reception path formed by the antenna terminal, the third switch, the low noise amplifier, and the receiving terminal.

20. The operating method of claim 16, wherein the front end module further comprises a first matching network connected between the first switch and the node, and
in the second mode, the second receiving signal passes through a reception bypass path formed by the antenna terminal, the first switch, the first matching network, the second switch, and the transmitting terminal.
